(19) United States
(12) Patent Application Publication
(10) Pub. No.: US 2013/0026574 A1
(43) Pub. Date: Jan. 31, 2013

(54) SEMICONDUCTOR DEVICE, METHOD FOR MANUFACTURING SAME, AND DISPLAY DEVICE

(71) Applicants: Kenji Nakanishi, Osaka-shi (JP); Masao Moriguchi, Osaka-shi (JP); Atsuyuki Hoshino, Osaka-shi (JP)

(72) Inventors: Kenji Nakanishi, Osaka-shi (JP); Masao Moriguchi, Osaka-shi (JP); Atsuyuki Hoshino, Osaka-shi (JP)

(21) Appl. No.: 13/639,122

(22) PCT Filed: Jan. 25, 2011
(86) PCT No.: PCT/JP2011/051269

§ 371 Date: Oct. 3, 2012

(30) Foreign Application Priority Data
Apr. 30, 2010 (JP) 2010-104765

(51) Int. Cl. H01L 29/78; H01L 21/28

(52) U.S. Cl. 257/347; 438/684; 257/E29.255; 257/E21.158

(57) ABSTRACT

In an inverted staggered type TFT (100), contact layers (150a and 150b) that electrically connect a channel layer (140) to source and drain electrodes (160a and 160b), respectively, include n⁺ amorphous silicon layers (151a and 151b), n⁺ microcrystalline silicon layers (152a and 152b), and n⁺ microcrystalline silicon layers (153a and 153b). The n⁺ microcrystalline silicon layers (152a and 152b) have a lower crystallization rate than the n⁺ microcrystalline silicon layers (153a and 153b) and are formed between the n⁺ amorphous silicon layers (151a and 151b) and the n⁺ microcrystalline silicon layers (153a and 153b). In this case, since the film thickness of incubation layers formed on surfaces of the n⁺ amorphous silicon layers (151a and 151b) decreases, the resistance value of the contact layers (150a and 150b) decreases. By this, the contact resistance of the TFT (100) decreases and the mobility can be increased.

### TECHNICAL FIELD

The present invention relates to a semiconductor device, a method for manufacturing a semiconductor device, and a display device, and more particularly to a switching element included in each pixel formation portion of an active matrix-type display device or a semiconductor device suitable as a thin film transistor composing a drive circuit, and a manufacturing method therefor and a display device.

### BACKGROUND ART

Conventionally, in a thin film transistor (hereinafter, referred to as a “TFT”), as contact layers that electrically connect a channel layer to source and drain electrodes, respectively, amorphous silicon layers or polycrystalline silicon layers formed by performing an annealing process such as laser annealing on amorphous silicon layers are used. However, there is a problem that the mobility of the amorphous silicon layers is as low as the order of 0.5 cm²/V·sec. On the other hand, the mobility of the polycrystalline silicon layers is as high as about 100 cm²/V·sec; however, since the polycrystalline silicon layers require an annealing process, there is a problem that a contact layer formation step becomes complicated.

In view of this, in recent years, microcrystalline silicon layers having a higher mobility than the amorphous silicon layers and not requiring an annealing process have started to be used as the contact layers of a TFT. However, the growth rate of microcrystalline silicon is on the order of about one-half that of amorphous silicon. Hence, there is a problem that the formation of contact layers made of microcrystalline silicon layers requires a long period of time.

Japanese Patent Application Laid-Open No. 8-172195 describes an inverted staggered type TFT including, on a channel layer, contact layers each made of a stacked silicon layer including a microcrystalline silicon layer. Specifically, it describes that the TFT uses, as a contact layer, a stacked silicon layer of a two-layer structure having an n⁺ amorphous silicon layer doped with high concentrations of n-type impurities and an n⁺ microcrystalline silicon layer doped with high concentrations of n-type impurities, which are stacked on top of each other in this order from the channel layer side. By this, the resistance value of the contact layers can be reduced and the time required for the formation of the contact layers can be reduced.

### PRIOR ART DOCUMENT

### Patent Document

[Patent Document 1] Japanese Patent Application Laid-Open No. 8-172195

### SUMMARY OF THE INVENTION

### Problems to be Solved by the Invention

However, in a TFT using, as a contact layer, a stacked silicon layer having an n⁺ microcrystalline silicon layer stacked on a surface of an n⁺ amorphous silicon layer, like a TFT described in Japanese Patent Application Laid-Open No. 8-172195, a phenomenon appears in which the contact resistance increases, resulting in a reduction in mobility. This is considered to be due to the following reason. Specifically, when an n⁺ microcrystalline silicon layer is stacked on a surface of an n⁺ amorphous layer, first, an incubation layer with a thickness of several nm grows on the surface of the n⁺ amorphous silicon layer, and then, a microcrystalline silicon layer grows on the incubation layer. The incubation layer is a precursor before a microcrystalline silicon layer grows, and contains many voids therein. Therefore, it is considered that since the larger the film thickness of the incubation layer, the higher the resistance value of the contact layer, the contact resistance of the TFT increases and the mobility decreases.

An object of the present invention is therefore to provide a semiconductor device including contact layers with a low resistance value. In addition, another object of the present invention is to provide a method for manufacturing a semiconductor device capable of easily manufacturing such a semiconductor device.

### Means for Solving the Problems

A first aspect of the present invention is directed to a semiconductor device comprising a gate electrode, a gate insulating film, a channel layer, and source and drain electrodes stacked on top of one another on an insulating substrate in this order or in reverse order thereto, wherein

the semiconductor device further comprises two contact layers formed between the channel layer and the source electrode and between the channel layer and the drain electrode so as to be separated from each other, and

each of the contact layers has a first microcrystalline semiconductor layer and a second microcrystalline semiconductor layer stacked on top of each other in order of the first microcrystalline semiconductor layer and the second microcrystalline semiconductor layer from a side of the channel layer, the first microcrystalline semiconductor layer containing a conductive impurity, and the second microcrystalline semiconductor layer containing a conductive impurity of a same type as that of the first microcrystalline semiconductor layer and having a higher crystallization rate than the first microcrystalline semiconductor layer.

A second aspect of the present invention is such that in the first aspect of the present invention,

the gate electrode is formed on the insulating substrate,

the gate insulating film is formed so as to cover the gate electrode,

the channel layer is formed on a portion of a surface of the gate insulating film corresponding to the gate electrode,

each of the contact layers is formed such that a stacked film is formed on a surface of the channel layer, the stacked film having the second microcrystalline semiconductor layer stacked on a surface of the first microcrystalline semiconductor layer, and

the source and drain electrodes are respectively formed on surfaces of the second microcrystalline semiconductor layers.

A third aspect of the present invention is such that in the first aspect of the present invention,

the source and drain electrodes are formed on the insulating substrate,

the contact layers are formed such that stacked films are formed on surfaces of the source and drain electrodes, respectively, so as to be spaced from each other by a predetermined distance, the stacked films each having the first microcrystalline semiconductor layer stacked on a surface of the second microcrystalline semiconductor layer,

the channel layer is formed so as to cover a portion of the insulating substrate sandwiched between the contact layers, and surfaces of the first microcrystalline semiconductor layers of the contact layers,

the gate insulating film is formed so as to cover the channel layer, and

the gate electrode is formed on a portion of a surface of the gate insulating film corresponding to the portion of the insulating substrate sandwiched between the contact layers.

A fourth aspect of the present invention is such that in the second or third aspect of the present invention,

each of the contact layers further includes an amorphous semiconductor layer between the first microcrystalline semiconductor layer and the channel layer, the amorphous semiconductor layer containing a conductive impurity of a same type as that of the first microcrystalline semiconductor layer.

A fifth aspect of the present invention is such that in the fourth aspect of the present invention,

each of the first microcrystalline semiconductor layers includes a plurality of microcrystalline semiconductor layers having different crystallization rates, and

the plurality of microcrystalline semiconductor layers include microcrystalline semiconductor layers formed such that crystallization rates thereof increase in turn from the side of the channel layer toward the second microcrystalline semiconductor layer.

A sixth aspect of the present invention is such that in the fourth aspect of the present invention,

the crystallization rate of the first microcrystalline semiconductor layers is between 1 and 2, inclusive.

A seventh aspect of the present invention is directed to a method for manufacturing a semiconductor device having a gate electrode, a gate insulating film, a channel layer, contact layers, and source and drain electrodes stacked on top of one another in this order on an insulating substrate, wherein

each of the contact layers includes a first microcrystalline semiconductor layer containing a conductive impurity; and a second microcrystalline semiconductor layer containing an conductive impurity of a same type as that of the first microcrystalline semiconductor layer, and

a step of forming each of the contact layers includes:
a step of forming the first microcrystalline semiconductor layer on a surface of the channel layer; and
a step of forming the second microcrystalline semiconductor layer on a surface of the first microcrystalline semiconductor layer at a higher flow ratio of hydrogen gas to raw material gas than that for the step of forming the first microcrystalline semiconductor layer.

An eighth aspect of the present invention is such that in the seventh aspect of the present invention,

the step of forming each of the contact layers further includes:

a step of forming an amorphous semiconductor layer on the surface of the channel layer prior to the step of forming the first microcrystalline semiconductor layer.

A ninth aspect of the present invention is such that in the eighth aspect of the present invention,

each of the first microcrystalline semiconductor layers includes a plurality of microcrystalline semiconductor layers having different crystallization rates, and

in the step of forming the first microcrystalline semiconductor layer, a flow ratio of hydrogen gas to raw material gas increases in turn for every formation of a microcrystalline semiconductor layer included in the plurality of microcrystalline semiconductor layers.

A tenth aspect of the present invention is such that in the eighth aspect of the present invention,

in the step of forming the first microcrystalline semiconductor layer, the flow ratio of hydrogen gas to raw material gas is 1:25 to 1:75.

An eleventh aspect of the present invention is directed to a display device comprising a semiconductor device according to any one of claims 1 to 6 formed on an insulating substrate.

### Effects of the Invention

According to the first aspect, each contact layer of the semiconductor device has a first microcrystalline semiconductor layer and a second microcrystalline semiconductor layer having a higher crystallization rate than the first semiconductor layer, which are stacked on top of each other in the order of the first microcrystalline semiconductor layer and the second microcrystalline semiconductor layer from the channel layer side. In this case, the film thickness of incubation layers formed on the surfaces, on the channel layer side, of the first microcrystalline semiconductor layers can be reduced. By this, since the resistance value of the contact layers decreases, the contact resistance of the semiconductor device decreases, enabling to increase the mobility.

According to the second aspect, the semiconductor device is of an inverted staggered type and has first microcrystalline semiconductor layers and second microcrystalline semiconductor layers having a higher crystallization rate than the first microcrystalline semiconductor layers, which are stacked on top of each other in this order on a surface of a channel layer. In this case, the film thickness of incubation layers formed on the surfaces, on the channel layer side, of the first microcrystalline semiconductor layers can be reduced. By this, since the resistance value of the contact layers decreases, the contact resistance of the semiconductor device decreases, enabling to increase the mobility.

According to the third aspect, the semiconductor device is of a staggered type and has a channel layer formed on surfaces of first microcrystalline semiconductor layers of contact layers. By this, even in the staggered type semiconductor device, as with the inverted staggered type semiconductor device, the contact resistance decreases, enabling to increase the mobility.

According to the fourth aspect, since each contact layer further includes an amorphous semiconductor layer of the same conductive type as that of the first microcrystalline semiconductor layer between the first microcrystalline semiconductor layer and the channel layer, the film thickness of the contact layers increases and thus the resistance value decreases. By this, the contact resistance of the semiconductor device decreases, enabling to increase the mobility.

According to the fifth aspect, each first microcrystalline semiconductor layer includes a plurality of microcrystalline semiconductor layers having different crystallization rates. The plurality of microcrystalline semiconductor layers include microcrystalline semiconductor layers stacked on top of each other such that their crystallization rates increase in turn from the channel layer side toward the second microcrystalline semiconductor layer. In this case, the difference in crystallization rate between the channel layer and the first microcrystalline semiconductor layers, and the difference in crystallization rate between the plurality of microcrystalline semiconductor layers can be minutely adjusted. Thus, the growth of incubation layers formed on a surface of the channel layer and surfaces of the plurality of microcrystalline semiconductor layers can be further suppressed. By this, the contact resistance of the semiconductor device further decreases, enabling to further increase the mobility.

According to the sixth aspect, the crystallization rate of the microcrystalline semiconductor layers included in the first microcrystalline semiconductor layers is set between 1 and 2, inclusive. By this, when first microcrystalline semiconductor layers are formed on surfaces of amorphous semiconductor layers, the growth of incubation layers formed on the surfaces of the amorphous semiconductor layers is suppressed and thus the resistance value of the contact layers decreases. By this, the contact resistance of the semiconductor device decreases, enabling to increase the mobility.

According to the seventh aspect, after forming first microcrystalline semiconductor layers, second microcrystalline semiconductor layers are formed on surfaces of the first microcrystalline semiconductor layers under the condition that the flow ratio of hydrogen gas to raw material gas is higher than that in the step of forming the first microcrystalline semiconductor layer. In this case, since the crystallization rate of the first microcrystalline semiconductor layers is lower than that of the second semiconductor layers, the growth of incubation layers formed on the surfaces, on the channel layer side, of the first microcrystalline semiconductor layers is suppressed and thus the resistance value of the contact layers decreases. By thus adjusting the flow ratio of hydrogen gas to raw material gas, a semiconductor device with a low contact resistance and a high mobility can be easily manufactured.

According to the eighth aspect, after forming a channel layer, amorphous semiconductor layers are formed on a surface of the channel layer before forming first microcrystalline semiconductor layers. Thus, the film thickness of contact layers increases and the resistance value decreases. By this, a semiconductor device with a low contact resistance and a high mobility can be easily manufactured.

According to the ninth aspect, to form a plurality of microcrystalline semiconductor layers in turn in ascending order of crystallization rate from the channel layer side, the flow ratio of hydrogen gas to raw material gas is allowed to increase in turn for every microcrystalline semiconductor layer. In this case, the difference in crystallization rate between the channel layer and the first microcrystalline silicon layers, and the difference in crystallization rate between the plurality of microcrystalline silicon layers can be minutely adjusted. Thus, the growth of incubation layers formed on a surface of the channel layer and surfaces of the plurality of microcrystalline semiconductor layers can be further suppressed. By thus more minutely adjusting the flow ratio of hydrogen gas to raw material gas, a semiconductor device with a low contact resistance and a high mobility can be easily manufactured.

According to the tenth aspect, first microcrystalline semiconductor layers are formed on surfaces of amorphous semiconductor layers under the condition that the flow ratio of hydrogen gas to raw material gas is 1:25 to 1:75. By this, the growth of incubation layers formed on surfaces of the amorphous semiconductor layers is suppressed and thus the resistance value of contact layers decreases. By thus adjusting the flow ratio of hydrogen gas to raw material gas, a semiconductor device with a low contact resistance and a high mobility can be easily manufactured.

According to the eleventh aspect, by forming switching elements of pixel formation portions of a display device using semiconductor devices according to the first to sixth aspects, the current flowing through the switching elements increases. By this, the switching elements can charge video signals in pixel capacitances in a short time, enabling to achieve high definition of the display device by increasing the number of pixel formation portions. In addition, by forming a drive circuit using semiconductor devices according to the first to tenth aspects, the operating speed of the drive circuit can be increased. As a result, the circuit size of the drive circuit can be reduced, enabling to miniaturize the display device and achieve low power consumption of the display device.

### BRIEF DESCRIPTION OF THE DRAWINGS

FIG. 1 is a cross-sectional view showing a configuration of an inverted staggered type TFT according to a first embodiment.

(a) to (d) of FIG. 2 are step cross-sectional views showing the manufacturing steps of the TFT shown in FIG. 1.

(a) to (c) of FIG. 3 are step cross-sectional views showing the manufacturing steps of the TFT shown in FIG. 1.

FIG. 4 is a diagram showing various electrical characteristics of the TFT shown in FIG. 1.

FIG. 5 is a diagram showing the gate voltage-drain current characteristics of TFTs manufactured under conditions shown in FIG. 4.

FIG. 6 is a cross-sectional view showing a configuration of an inverted staggered type TFT according to a second embodiment.

FIG. 7 is a cross-sectional view showing a configuration of a staggered type TFT according to a third embodiment.

(a) of FIG. 8 is a diagram showing a configuration of a liquid crystal panel included in an active matrix-type liquid crystal display device, and (b) of FIG. 8 is a diagram showing a configuration of a TFT substrate included in the liquid crystal panel shown in (a) of FIG. 8.

### MODES FOR CARRYING OUT THE INVENTION

### 1. First Embodiment

### 1.1 Configuration of a TFT

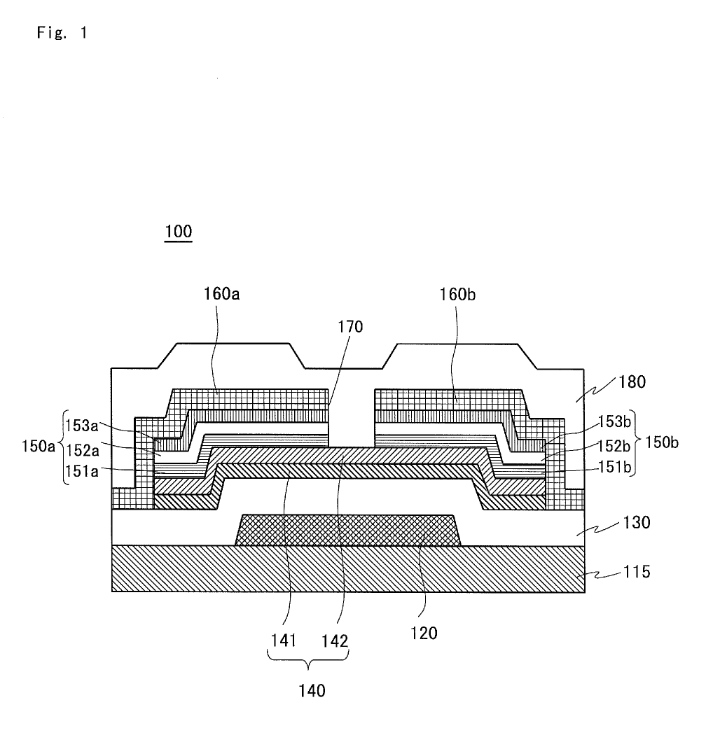

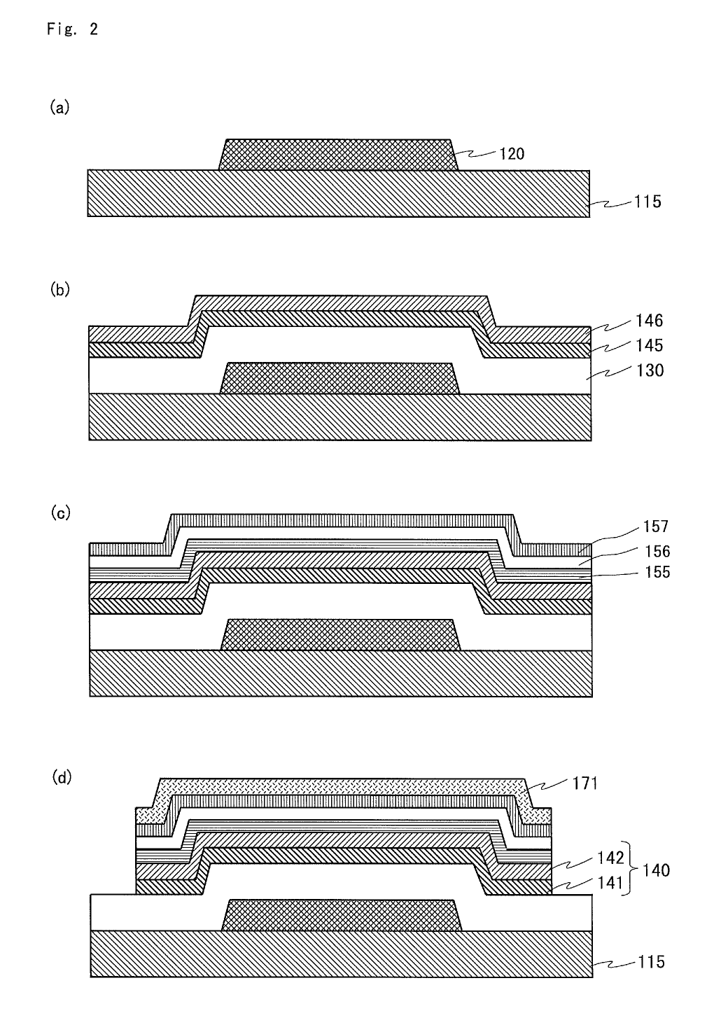

A configuration of an inverted staggered type TFT 100 according to a first embodiment of the present invention will be described. FIG. 1 is a cross-sectional view showing a configuration of an inverted staggered type TFT 100. A gate electrode 120 made of metal is formed on a glass substrate 115 which is an insulating substrate. A gate insulating film 130 made of a silicon nitride film is formed so as to cover the entire glass substrate 115 including the gate electrode 120. The film thickness of the gate insulating film 130 is, for example, 300 nm.

An island-like channel layer 140 extending laterally over the gate electrode 120 as viewed from the top is formed on a surface of the gate insulating film 130. The channel layer 140 has a two-layer structure having an intrinsic amorphous silicon layer 142 stacked on a surface of an intrinsic microcrystalline silicon layer 141 not containing impurities. The film thickness of the microcrystalline silicon layer 141 is, for example 25 nm, and the film thickness of the amorphous silicon layer 142 is, for example, 100 nm. Note that the channel layer 140 may be composed of only an intrinsic amorphous silicon layer, and the film thickness of the amorphous silicon layer in that case is, for example, 100 nm. Furthermore, a channel protective film may be provided on a surface of the channel layer 140 so as to prevent the surface of the channel layer 140 from being etched upon formation of contact layers 150a and 150b which will be described later.

A contact layer 150a is formed on a portion of the surface of the channel layer 140 on the left side, and a contact layer 150b is formed on a portion of the surface of the channel layer 140 on the right side. The contact layer 150a and the contact layer 150b are separated from each other to the left and right on the channel layer 140 by an opening 170.

The contact layers 150a and 150b each are a stacked silicon layer having three silicon layers including an n⁺ amorphous silicon layer 151a, 151b; an n⁺ microcrystalline silicon layer 152a, 152b; and an n⁺ microcrystalline silicon layer 153a, 153b, which are stacked on top of one another in this order from the side of the channel layer 140. When the film thickness of the contact layers 150a and 150b is, for example, 75 nm, the film thickness of the n⁺ amorphous silicon layers 151a and 151b is 15 nm, the film thickness of the n⁺ microcrystalline silicon layers 152a and 152b is 15 nm, and the film thickness of the n⁺ microcrystalline silicon layers 153a and 153b is 45 nm. In this case, to make full use of the characteristics that microcrystalline silicon has a low resistance value and a high mobility, it is preferred that the film thickness of the n⁺ microcrystalline silicon layers 153a and 153b which greatly affect the resistance value of the contact layers 150a and 150b be at least 40 nm.

The n⁺ microcrystalline silicon layers 153a and 153b are doped with high concentrations of n-type impurities so as to be ohmic-connected to a source electrode 160a and a drain electrode 160b, respectively. The impurity concentration of the n⁺ microcrystalline silicon layers 152a and 152b is the same as that of the n⁺ microcrystalline silicon layers 153a and 153b. However, they have different crystallization rates and different grain sizes. While the crystallization rate of the n⁺ microcrystalline silicon layers 153a and 153b is 2.9, the crystallization rate of the n⁺ microcrystalline silicon layers 152a and 152b is as low as 1.1 to 1.9. In this specification, the crystallization rate is expressed by Ic/Ia. Here, Ic is the Raman signal strength of a microcrystalline component which is determined by Raman spectrometry, and Ia is the Raman signal strength of an amorphous component. Therefore, it indicates that the higher the crystallization rate, the higher the proportion of the microcrystalline component. When the grain size of the n⁺ microcrystalline silicon layers 153a and 153b is 1, the grain size of the n⁺ microcrystalline silicon layers 152a and 152b is as small as about ½ to ⅘. As such, the n⁺ microcrystalline silicon layers 152a and 152b are made of silicon layers whose crystallization is not advanced as much as the n⁺ microcrystalline silicon layers 153a and 153b.

The source electrode 160a extending from a right edge of the contract layer 150a to the gate insulating film 130 so as to cover the contact layer 150a, and the drain electrode 160b extending from a left edge of the contract layer 150b to the gate insulating film 130 so as to cover the contact layer 150b are formed. The source electrode 160a and the drain electrode 160b are made of metal. The source electrode 160a is electrically connected to the channel layer 140 through the contact layer 150a, and the drain electrode 160b is electrically connected to the channel layer 140 through the contact layer 150b. Furthermore, a protective film 180 made of a silicon nitride film is formed so as to cover the entire glass substrate 115 including the source electrode 160a and the drain electrode 160b.

### 1.2 Method for Manufacturing a TFT

Next, a method for manufacturing a TFT 100 will be described. (a) to (d) of FIG. 2 and (a) to (c) of FIG. 3 show step cross-sectional views showing the manufacturing steps of a TFT 100 shown in FIG. 1. With reference to (a) to (d) of FIG. 2 and (a) to (c) of FIG. 3, a method for manufacturing a TFT 100 will be described. First, a metal film (not shown) having, for example, a titanium (Ti) as its main component and a film thickness of 100 to 500 nm, preferably, 200 nm is deposited on a glass substrate 115 using a sputtering method. Note that instead of the metal film having titanium as its main component, a metal film having tungsten (W), molybdenum (Mo), aluminum (Al), etc., as its main component, or a stacked metal film having those layers stacked on top of each other may be deposited.

A resist pattern (not shown) is formed on a surface of the metal film using a photolithography method. As shown in (a) of FIG. 2, the metal film is etched by a wet etching method, using the resist pattern as a mask, thereby forming a gate electrode 120. Thereafter, the resist pattern is removed. Note that the gate electrode 120 may be formed using a dry etching method instead of a wet etching method.

As shown in (b) of FIG. 2, a silicon nitride film is deposited using a plasma CVD (Chemical Vapor Deposition) method so as to cover the entire glass substrate 115 including the gate electrode 120. The silicon nitride film functions as a gate insulating film 130. The gas used to deposit a silicon nitride film includes monosilane gas (SiH₄), ammonia gas (NH₃), and nitrogen gas (N₂). The film thickness of the silicon nitride film is, for example, 200 to 500 nm, preferably, 350 nm. Note that as the gate insulating film 130, a silicon oxide (SiO₂) film or silicon oxynitride (SiON) film may be used instead of a silicon nitride film.

Furthermore, a microcrystalline silicon film 145 is deposited on a surface of the gate insulating film 130, using a high-density plasma CVD apparatus of an ICP (Inductively Coupled Plasma) system, a surface wave plasma system, etc. Furthermore, an amorphous silicon film 146 is deposited on a surface of the microcrystalline silicon film 145, using a plasma CVD method. The film thickness of the microcrystalline silicon film 145 is, for example, 20 to 30 nm, preferably, 25 nm. The film thickness of the amorphous silicon film 146 is, for example, 80 to 120 nm, preferably, 100 nm.

As shown in (c) of FIG. 2, an n⁺ amorphous silicon film 155 of a film thickness of, for example, 15 nm is deposited on a surface of the amorphous silicon film 146, using a plasma CVD method. The main deposition conditions of the n⁺ amorphous silicon film 155 are as follows. Note that when phosphorus (P) is doped as n-type impurities, phosphine gas (PH₃) is used.

Pressure in the chamber: 60 Pa

Discharge output: 0.04 kW

Gas flow ratio: PH₃:SiH₄:H₂=0.05:1:1

Then, an n⁺ microcrystalline silicon film 156 of a film thickness of, for example, 15 nm is deposited on a surface of the n⁺ amorphous silicon film 155, using a high-density plasma CVD method. The main deposition conditions of the n⁺ microcrystalline silicon film 156 are as follows:

Pressure in the chamber: 240 Pa

Discharge output: 1.0 kW

Note that the n⁺ microcrystalline silicon film 156 is deposited under the condition that the hydrogen gas flow ratio (hereinafter, referred to as the “H₂ dilution ratio”) for when the monosilane gas is 1 is lower than the H₂ dilution ratio for when an n⁺ microcrystalline silicon film 157 which will be described later is deposited. A specific H₂ dilution ratio will be described later.

Next, an n⁺ microcrystalline silicon film 157 of a film thickness of, for example, 45 nm is deposited on a surface of the n⁺ microcrystalline silicon film 156, using a high-density plasma CVD method. The main deposition conditions of the n⁺ microcrystalline silicon film 157 are as follows:

Pressure in the chamber: 240 Pa

Discharge output: 1.0 kW

Gas flow ratio: PH₃:SiH₄:H₂=0.05:1:150

As shown in (d) of FIG. 2, a resist pattern 171 is formed on a surface of the n⁺ microcrystalline silicon film 157, using a photolithography method. Using the resist pattern 171 as a mask, the n⁺ microcrystalline silicon film 157, the n⁺ microcrystalline silicon film 156, the n⁺ amorphous silicon film 155, the amorphous silicon film 146, and the microcrystalline silicon film 145 are consecutively etched in this order by a dry etching method. Thereafter, the resist pattern 171 is removed. By this, the island-like n⁺ microcrystalline silicon film 157, n⁺ microcrystalline silicon film 156, and n⁺ amorphous silicon film 155, and an island-like channel layer 140 including an amorphous silicon layer 142 and a microcrystalline silicon layer 141 are formed in a state of being stacked on top of one another.

As shown in (a) of FIG. 3, a metal film 161 is deposited by a sputtering method so as to cover the entire glass substrate 115. The metal film 161 is, for example, a metal film having titanium as its main component. The film thickness of the metal film 161 is, for example, 50 to 200 nm, preferably, 100 nm. Note that instead of the metal film 161 having titanium as its main component, a metal film having tungsten, molybdenum, aluminum, etc., as its main component, or a metal film having those layers stacked on top of each other may be deposited. A resist pattern 172 having an opening in a region corresponding to a central portion of the channel layer 140 is formed on a surface of the metal film 161, using a photolithography method.

As shown in (b) of FIG. 3, using the resist pattern 172 as a mask, the metal film 161 is etched by a wet etching method, thereby forming a source electrode 160a and a drain electrode 160b. Note that the metal film 161 may be etched using a plasma etching method instead of a wet etching method.

Furthermore, using the resist pattern 172 as a mask, the island-like n⁺ microcrystalline silicon film 157, n⁺ microcrystalline silicon film 156, and n⁺ amorphous silicon film 155 are etched in turn by a plasma etching method, thereby forming two contact layers 150a and 150b separated from each other to the left and right by an opening 170. At this time, to suppress a film reduction of the amorphous silicon layer 142 to a minimum, etching is performed under the condition that the selective ratio of the n⁺ amorphous silicon film 155 to the amorphous silicon layer 142 is high.

As shown in (c) of FIG. 3, a protective film 180 made of silicon nitride is deposited so as to cover the entire glass substrate 115 including the source electrode 160a and the drain electrode 160b. The protective film 180 is deposited using a plasma CVD method and the film thickness thereof is, for example, 200 nm. By the above-described series of manufacturing steps, the TFT 100 is manufactured.

### 1.3 Characteristics of the TFT

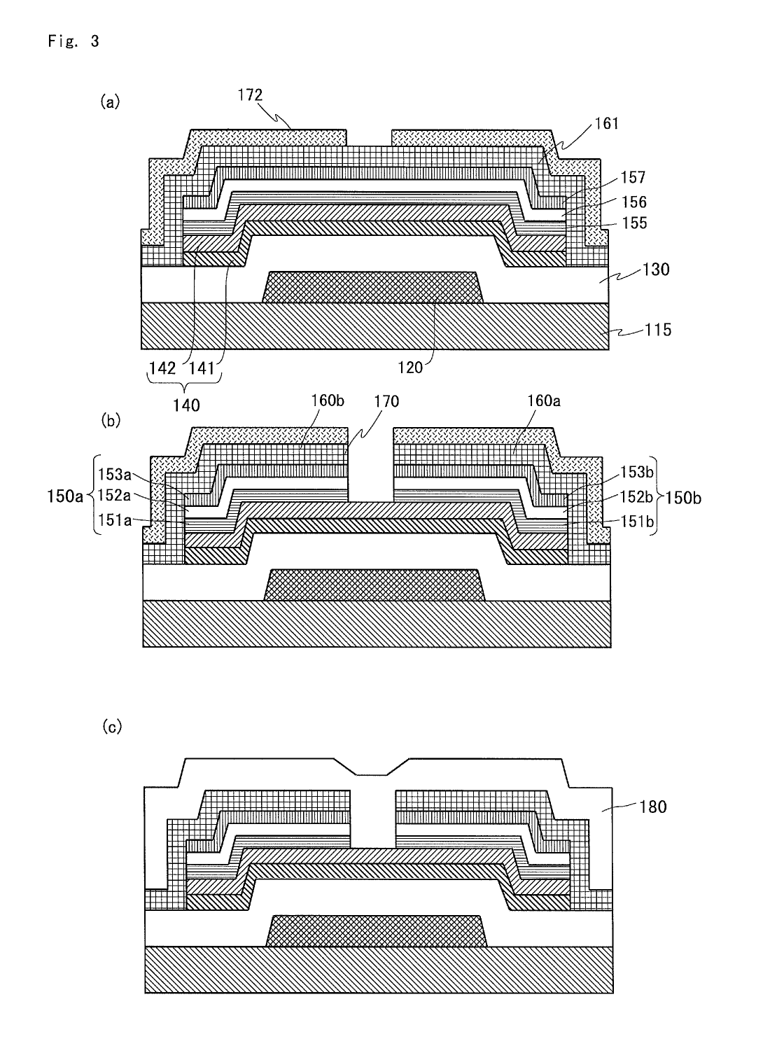

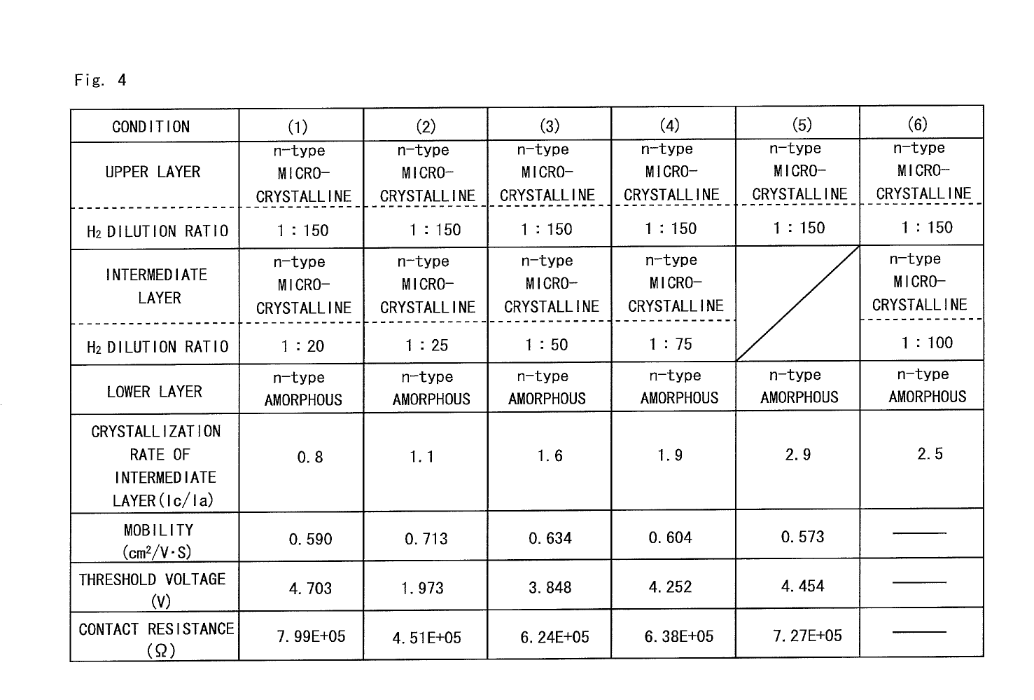

FIG. 4 is a diagram showing various electrical characteristics of TFTs 100. FIG. 4 describes the crystallization rate of n⁺ microcrystalline silicon layers 152a and 152b and the mobility, threshold voltage, and measured value of contact resistance of a TFT 100, for five types of TFTs 100 with different H₂ dilution ratios which are used upon deposition of n⁺ microcrystalline silicon layers 152a and 152b (intermediate layers) included in contact layers 150a and 150b. In all of the TFTs 100, a lower layer among three silicon layers included in each of the contact layers 150a and 150b is an n⁺ amorphous silicon layer 151a, 151b. In all of the TFTs 100, an upper layer is an n⁺ microcrystalline silicon layer 153a, 153b which is deposited under the condition that the H₂ dilution ratio is 150.

Of conditions (1) to (6) shown in FIG. 4, condition (5) indicates a conventional TFT including contact layers of a two-layer structure not including n⁺ microcrystalline silicon layers 152a and 152b. As shown in FIG. 4, the contact resistance in the case of condition (5) is higher compared to the case of conditions (2) to (4).

In general, when an n⁺ microcrystalline silicon layer is deposited on an n⁺ amorphous silicon layer, first, an incubation layer is formed on a surface of the n⁺ amorphous silicon layer. At this time, it is considered that the higher the crystallization rate of the n⁺ microcrystalline silicon layer deposited on the n⁺ amorphous silicon layer, the larger the film thickness of the incubation layer, and thus the resistance value of a contact layer increases.

In the case of conventional condition (5), an n⁺ microcrystalline silicon layer with a very high crystallization rate of 2.9 is deposited on an n⁺ amorphous silicon layer which is a lower layer. By this, it is considered that an incubation layer having a large film thickness is formed on a surface of the n⁺ amorphous silicon layer and thus the contact resistance of the TFT increases and the mobility decreases.

In the case of condition (1), despite the fact that n⁺ microcrystalline silicon layers 152a and 152b are formed, the contact resistance thereof is higher than the case of condition (5). The reason that the contact resistance thus increases is considered that since the crystallization rate of the n⁺ microcrystalline silicon layers 152a and 152b is as low as 0.8, microcrystalline components are not sufficiently grown in the n⁺ microcrystalline silicon layers 152a and 152b, and thus the resistance value of the n⁺ microcrystalline silicon layers 152a and 152b is high.

On the other hand, in the case of condition (2) to (4), both the contact resistance and the mobility are improved compared to the case of condition (5). This is considered to be due to the following reason. Specifically, in conditions (2) to (4), the crystallization rate of the n⁺ microcrystalline silicon layers 152a and 152b is 1.1 to 1.9 and is lower than a crystallization rate of the n⁺ microcrystalline silicon layers 153a and 153b, which are upper layers, of 2.9. By this, the difference in crystallization rate between the n⁺ amorphous silicon layers 151a and 151b and the n⁺ microcrystalline silicon layers 152a and 152b decreases. Hence, it is considered that by stacking the n⁺ microcrystalline silicon layers 152a and 152b on the n⁺ amorphous silicon layers 151a and 151b, the film thickness of incubation layers formed on the surfaces of the n⁺ amorphous silicon layers 151a and 151b decreases. It is considered that since the resistance value of the contact layers 150a and 150b decreases in this manner, the contact resistance of the TFT decreases and the mobility increases.

In addition, in the case of conditions (2) to (5), as the H₂ dilution ratio used upon formation of the n⁺ microcrystalline silicon layers 152a and 152b increases, such as 1:25, 1:50, and 1:75, the contact resistance increases and the mobility decreases. This is considered to be due to the following reason. As the H₂ dilution ratio increases, the crystallization rate of the n⁺ microcrystalline silicon layers 152a and 152b increases. Correspondingly, it is considered that the film thickness of incubation layers formed on the surfaces of the n⁺ amorphous silicon layers 151a and 151b increases and thus the resistance value of the contact layers 150a and 150b increases. Note that to verify the upper limit of the H₂ dilution ratio, n⁺ microcrystalline silicon layers 152a and 152b are formed under condition (6) that the H₂ dilution ratio is 1:100, and the crystallization rate thereof is measured. The crystallization rate in this case is 2.5, revealing that the crystallization rate is very close to a crystallization rate of 2.9 for conventional condition (5). From this fact, it is considered that to obtain a crystallization rate of 2 or less, the upper limit of the H₂ dilution ratio is set to about 1:75.

From the above results, it is found that to obtain a lower contact resistance of the TFT 100 than that of the case of conventional condition (5), the crystallization rate of the n⁺ microcrystalline silicon layers 152a and 152b is preferably in the range represented by the following equation (1):

1.0≦Ic/Ia≦2.0 (1).

By setting the crystallization rate of the n⁺ microcrystalline silicon layers 152a and 152b to be lower than 1, the proportion of microcrystalline components contained in the n⁺ microcrystalline silicon layers 152a and 152b decreases, and thus the resistance value of the n⁺ microcrystalline silicon layers 152a and 152b increases. In addition, by setting the crystallization rate of the n⁺ microcrystalline silicon layers 152a and 152b to be higher than 2, incubation layers having a large film thickness are formed at the interfaces between the n⁺ amorphous silicon layers 151a and 151b and the n⁺ microcrystalline silicon layers 152a and 152b, and thus, the resistance value of the contact layers 150a and 150b increases. As such, in both cases in which the crystallization rate is lower than 1 and is higher than 2, since the resistance value of the contact layers 150a and 150b increases, the contact resistance of the TFT 100 increases and the mobility decreases. Note that in FIG. 4 the crystallization rate for the H₂ dilution ratio being 1:25 is 1.1, and the crystallization rate for the H₂ dilution ratio being 1:75 is 1.9. However, taking into account variations in measured values of the crystallization rate, in equation (1), the lower and upper limits of the crystallization rate are set to 1 and 2, respectively.

In addition, it can be seen from FIG. 4 that in order for the crystallization rate of the n⁺ microcrystalline silicon layers 152a and 152b to satisfy the above equation (1), the H₂ dilution ratio used upon deposition of the n⁺ microcrystalline silicon layers 152a and 152b is preferably in the range of 1:25 to 1:75.

Note that as shown in FIG. 4 the threshold voltage also changes according to the H₂ dilution ratio used upon deposition of the n⁺ microcrystalline silicon layers 152a and 152b. However, the reason that the threshold voltage changes depending on the H₂ dilution ratio has not been found yet.

FIG. 5 is a diagram showing the gate voltage-drain current (Vg-Id) characteristics of TFTs 100 manufactured under the conditions shown in FIG. 4, and shows Vg-Id characteristics obtained when a voltage of 10 V is applied between the source and drain. Curves (1) to (5) shown in FIG. 5 respectively indicate the Vg-Id characteristics of the TFTs 100 including n⁺ microcrystalline silicon layers 152a and 152b deposited under conditions (1) to (5) shown in FIG. 4.

As shown in FIG. 5, the curves (1) to (4) show substantially the same characteristics as the curve (5) which shows the Vg-Id characteristic of a conventional TFT. Therefore, the TFTs 100 exhibiting the Vg-Id characteristics of the curves (1) to (4) are used in the same manner as the conventional TFT. Note that of them the curve (2) has a slightly high on-current compared to the other curves. It is considered that this is due to the fact that by setting the H₂ dilution ratio to be as low as 1:25, the growth of incubation layers formed at the interfaces between the n⁺ amorphous silicon layers 151a and 151b and the n⁺ microcrystalline silicon layers 152a and 152b is suppressed, reducing the resistance value of the contact layers 150a and 150b. In addition, the curve (4) has a slightly low off-current compared to the other curves. It is considered that this is due to the fact that by setting the H₂ dilution ratio to be as high as 1:75, incubation layers having a large film thickness are formed at the interfaces between the n⁺ amorphous silicon layers 151a and 151b and the n⁺ microcrystalline silicon layers 152a and 152b, increasing the resistance value of the contact layers 150a and 150b.

### 1.4 Effects

As is clear from the above description, in the contact layers 150a and 150b of the TFT 100, the n⁺ microcrystalline silicon layers 152a and 152b lower in crystallization rate than the n⁺ microcrystalline silicon layers 153a and 153b are formed on the surfaces of the n⁺ amorphous silicon layers 151a and 151b. By this, the film thickness of incubation layers formed on the surfaces of the n⁺ amorphous silicon layers 151a and 151b decreases, enabling to reduce the resistance value of the contact layers 150a and 150b. By this, the contact resistance of the TFT 100 decreases, enabling to increase mobility.

In addition, since the contact layers 150a and 150b include the n⁺ amorphous silicon layers 151a and 151b formed on the surface of the channel layer 140, the film thickness of the contact layers 150a and 150b increases, enabling to reduce the resistance value. By this, the contact resistance of the TFT 100 decreases, enabling to increase the mobility.

In addition, by depositing the n⁺ microcrystalline silicon film 156 under the condition that the H₂ dilution ratio is lower than that used upon deposition of the n⁺ microcrystalline silicon film 157, the contact layers 150a and 150b that suppress the growth of incubation layers formed on the surfaces of the n⁺ amorphous silicon layers 151a and 151b can be easily formed. In particular, by forming the n⁺ microcrystalline silicon film 156 under the condition that the H₂ dilution ratio is 1:25 to 1:75, the contact layers 150a and 150b that suppress the growth of incubation layers formed on the surfaces of the n⁺ amorphous silicon layers 151a and 151b can be easily formed.

### 1.5 Variants

In the TFT 100, the n⁺ microcrystalline silicon layers 152a and 152b are described to be composed of a single n⁺ microcrystalline silicon layer. However, the n⁺ microcrystalline silicon layers 152a and 152b each may be composed of a plurality of n⁺ microcrystalline silicon layers having different crystallization rates. In this case, in each of the n⁺ microcrystalline silicon layers 152a and 152b, n⁺ microcrystalline silicon layers are stacked on top of each other such that their crystallization rates increase in turn from the surface of the n⁺ amorphous silicon layer 151a, 151b toward the n⁺ microcrystalline silicon layer 153a, 153b. Specifically, microcrystalline silicon films are stacked on top of each other such that a microcrystalline silicon film formed on a surface of each of the n⁺ amorphous silicon layers 151a and 151b has the lowest crystallization rate, and the crystallization rate increases as going away from the surface of each of the n⁺ amorphous silicon layers 151a and 151b. By this, the difference in crystallization rate between the n⁺ amorphous silicon layers 151a and 151b and the n⁺ microcrystalline silicon layers 152a and 152b, and the difference in crystallization rate between the plurality of n⁺ microcrystalline silicon layers can be minutely adjusted. Thus, the growth of incubation layers formed on the surfaces of the n⁺ amorphous silicon layers 151a and 151b and the surfaces of the plurality of n⁺ microcrystalline silicon layers can be further suppressed. Hence, the contact resistance of the TFT further decreases, enabling to further increase the mobility. In addition, to stack the n⁺ microcrystalline silicon layers on top of each other in turn such that their crystallization rates increase in turn from the surfaces of the n⁺ amorphous silicon layers 151a and 151b, it only needs to increase the H₂ dilution ratio in turn for every microcrystalline semiconductor layer. By this, the contact layers 150a and 150b each including a plurality of n⁺ microcrystalline silicon layers can be easily formed.

### 2. Second Embodiment

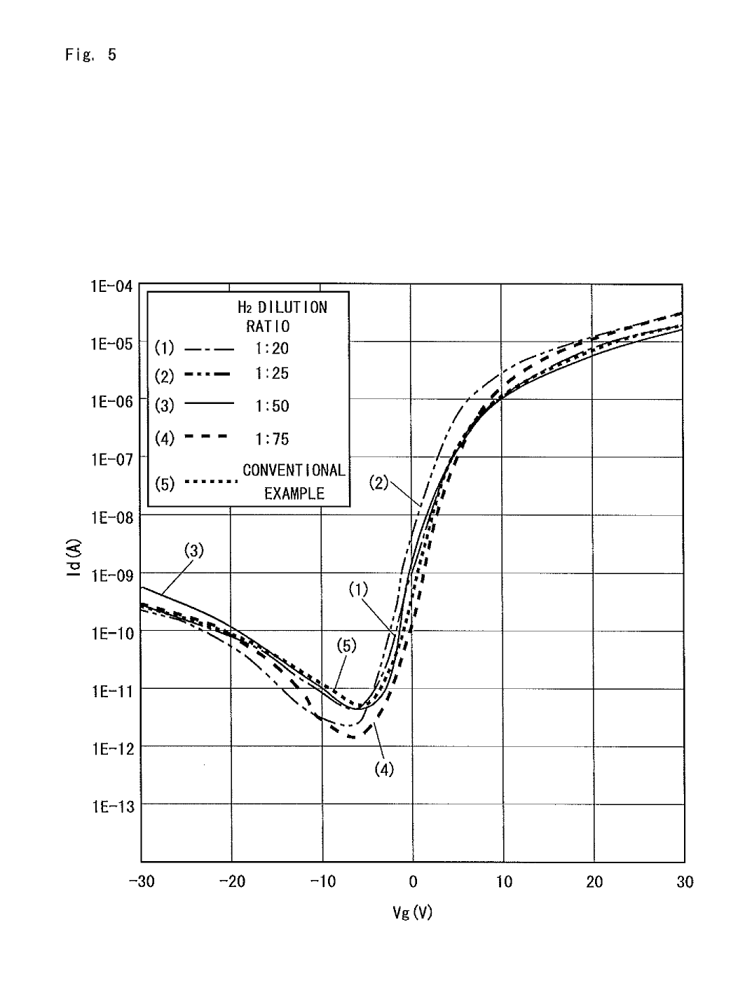

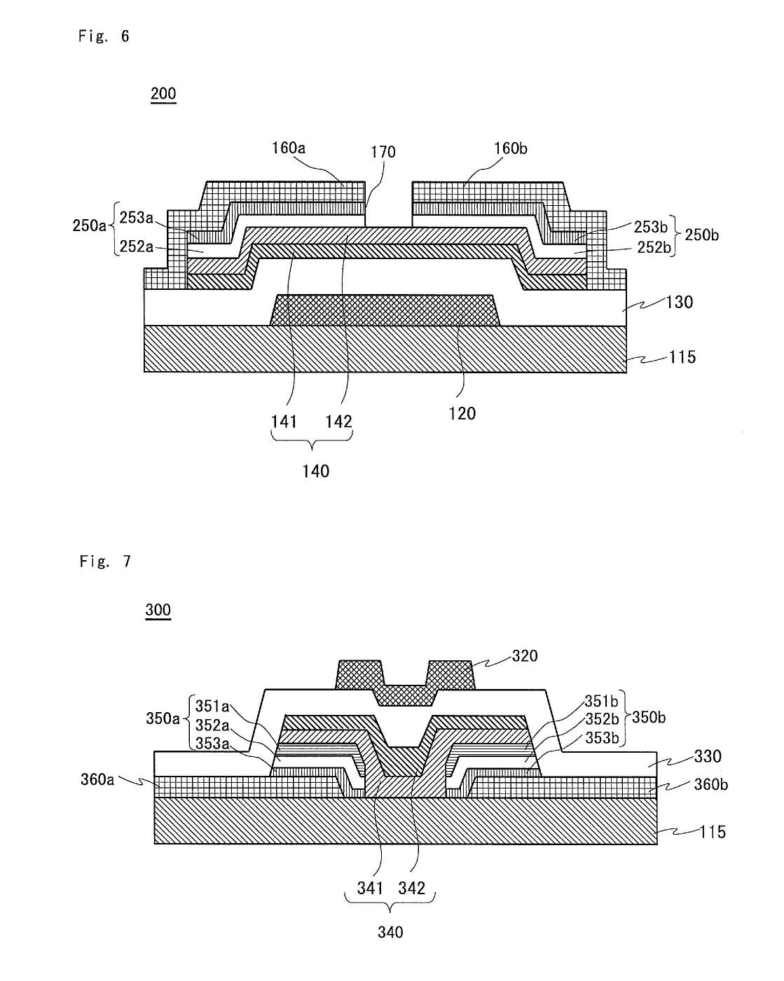

A configuration of a TFT 200 according to a second embodiment of the present invention will be described. FIG. 6 is a cross-sectional view showing a configuration of an inverted staggered type TFT 200. Of the components of the TFT 200 shown in FIG. 6, the same components as those of a TFT 100 shown in FIG. 1 are denoted by the same reference characters and different components will be mainly described.

As shown in FIG. 6, contact layers 250a and 250b of the TFT 200 have a two-layer structure. Specifically, the contact layers 250a and 250b formed on a surface of a channel layer 140 each are a stacked silicon layer having an n⁺ microcrystalline silicon layer 252a, 252b and an n⁺ microcrystalline silicon layer 253a, 253b which are stacked on top of each other in this order from the side of the channel layer 140. When the film thickness of the contact layers 250a and 250b is, for example, 60 nm, the film thickness of the n⁺ microcrystalline silicon layers 252a and 252b is 15 nm and the film thickness of the n⁺ microcrystalline silicon layers 253a and 253b is 45 nm. As such, the contact layers 250a and 250b of the TFT 200 do not include n⁺ amorphous silicon layers 151a and 151b which are included in contact layers 150a and 150b of a TFT 100.

In addition, a method for manufacturing a TFT 200 is such that in a method for manufacturing a TFT 100 shown in (a) to (d) of FIG. 2 and (a) to (c) of FIG. 3, in a step cross-sectional view shown in (c) of FIG. 2, an n⁺ microcrystalline silicon film 156 and an n⁺ microcrystalline silicon film 157 are deposited in turn on a surface of an amorphous silicon film 146 without depositing an n⁺ amorphous silicon film 155. Note that the deposition conditions and film thicknesses of the n⁺ microcrystalline silicon film 156 and the n⁺ microcrystalline silicon film 157 are the same as those in the case of the first embodiment and thus description thereof is omitted.

In addition, since the contact layers 250a and 250b are formed to have a two-layer structure, as shown in a step cross-sectional view shown in (b) of FIG. 3, the n⁺ microcrystalline silicon film 157 and the n⁺ microcrystalline silicon film 156 are etched in this order, thereby forming contact layers 250a and 250b.

By forming the contact layers 250a and 250b of the TFT 200 to have a two-layer structure, the resistance value of the contact layers 250a and 250b can be reduced to a level comparable to that of the contact layers 150a and 150b of the TFT 100 according to the first embodiment. By this, the TFT 200 can bring about the same effects as the TFT 100. In addition, since the structure of the contact layers 250a and 250b is simplified, the manufacturing steps of the TFT 200 are simplified, reducing manufacturing costs.

### 3. Third Embodiment

A configuration of a staggered type TFT 300 according to a third embodiment of the present invention will be described.

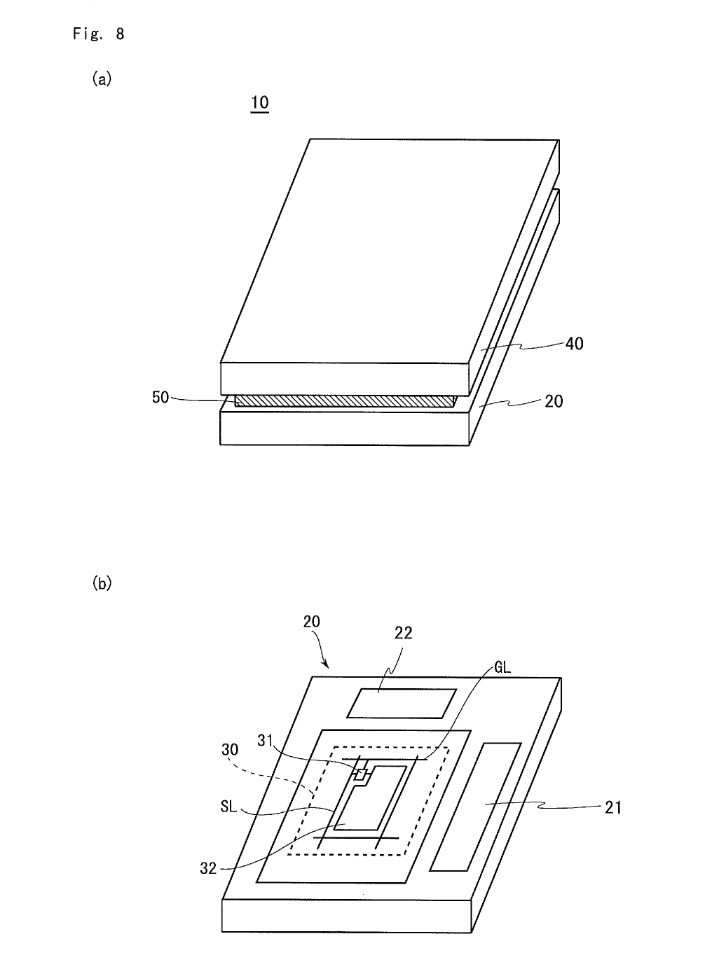

FIG. 7 is a cross-sectional view showing a configuration of a staggered type TFT 300.

As shown in FIG. 7, a source electrode 360a and a drain electrode 360b are formed on a glass substrate 115 so as to be spaced from each other by a predetermined distance. A contact layer 350a is formed from one edge of the source electrode 360a so as to cover a part of a surface thereof, and a contact layer 350b is formed from one edge of the drain electrode 360b so as to cover a part of a surface thereof and to be spaced from the contact layer 350a by a predetermined distance. A channel layer 340 is formed so as to cover the surfaces of the contact layers 350a and 350b and a portion of the glass substrate 115 sandwiched between the two contact layers 350a and 350b. A gate insulating film 330 is formed so as to cover the entire glass substrate 115 including the channel layer 340, and a gate electrode 320 is formed at a location on the gate insulating film 330 corresponding to a region sandwiched between the source electrode 360a and the drain electrode 360b. Furthermore, the TFT 300 is covered by a protective film (not shown).

The contact layers 350a and 350b each are formed of a stacked silicon layer having an n⁺ microcrystalline silicon layer 353a, 353b, an n⁺ microcrystalline silicon layer 352a, 352b, and an n⁺ amorphous silicon layer 351a, 351b which are stacked on top of one another in this order from the side of the source/drain electrode 360a, 360b. In addition, the channel layer 340 is made of a stacked silicon layer having an amorphous silicon layer 341 and a microcrystalline silicon layer 342 which are stacked on top of each other in this order from the side of the glass substrate 115. Note that the film thicknesses, deposition conditions, etc., of the layers are the same as those in the case of a TFT 100 according to the first embodiment and thus description thereof is omitted.

In the staggered type TFT 300, too, by forming the contact layers 350a and 350b to have a three-layer structure and setting the crystallization rate of the n⁺ microcrystalline silicon layers 352a and 352b to be lower than that of the n⁺ microcrystalline silicon layers 353a and 353b, the growth of incubation layers formed at the interfaces between the n⁺ amorphous silicon layers 351a and 351b and the n⁺ microcrystalline silicon layers 352a and 352b is suppressed. By this, the resistance value of the contact layers 350a and 350b decreases, and thus, the TFT 300 brings about the same effects as the TFT 100 according to the first embodiment. Note that it is preferred that the crystallization rate of the n⁺ microcrystalline silicon layers 352a and 352b be in the range between 1 and 2, inclusive, as in the case of the first embodiment.

In addition, although in the TFT 300 the contact layers 350a and 350b have a three-layer structure, the contact layers may have a two-layer structure. In this case, since the contact layers do not include n⁺ amorphous silicon layers 351a and 351b, a channel layer is formed on the surfaces of n⁺ microcrystalline silicon layers 352a and 352b. By this, the resistance value of the contact layers of the two-layer structure is reduced to a level comparable to that of the contact layers 350a and 350b. Hence, a TFT having contact layers of a two-layer structure can bring about the same effects as the TFT 300.

In addition, in a staggered type TFT, too, as in the case of a TFT 100, the n⁺ microcrystalline silicon layers 352a and 352b each may be composed of a plurality of n⁺ microcrystalline silicon layers having different crystallization rates. In this case, in each of the n⁺ microcrystalline silicon layers 352a and 352b, n⁺ microcrystalline silicon layers are stacked on top of each other such that their crystallization rates increase in turn from the surface of the n⁺ amorphous silicon layer 351a, 351b toward the n⁺ microcrystalline silicon layer 353a, 353b. By this, the growth of incubation layers formed on the surfaces of the n⁺ amorphous silicon layers 351a and 351b and the surfaces of the plurality of n⁺microcrystalline silicon layers can be further suppressed. Hence, the contact resistance of the TFT further decreases, enabling to further increase the mobility.

### 4. Liquid Crystal Display Device

(a) of FIG. 8 is a diagram showing a configuration of a liquid crystal panel 10 included in an active matrix-type liquid crystal display device, and (b) of FIG. 8 is a diagram showing a configuration of a TFT substrate 20 included in the liquid crystal panel 10 shown in (a) of FIG. 8. As shown in (a) of FIG. 8, the liquid crystal panel 10 includes two glass substrates disposed to face each other to sandwich a liquid crystal layer therebetween; the liquid crystal layer (not shown) sandwiched between the two glass substrates; and a sealing material 50 that seals the liquid crystal layer. Of the glass substrates, a glass substrate having a plurality of pixel formation portions including TFTs which are formed thereon in a matrix form is referred to as the TFT substrate 20, and a glass substrate disposed to face the TFT substrate 20 and having a color filter, etc., formed thereon is referred to as the CF substrate 40.

As shown in (b) of FIG. 8, the TFT substrate 20 includes pixel formation portions 30. Although (b) of FIG. 8 shows only one pixel formation portion 30 for convenience sake, the TFT substrate 20 has a plurality of pixel formation portions 30 formed thereon in a matrix form. In each pixel formation portion 30 are formed a TFT functioning as a switching element 31; and a pixel electrode 32 connected to the switching element 31. A gate driver 21 and a source driver 22 (the gate driver 21 and the source driver 22 may be collectively referred to as a “drive circuit”) are provided in a picture-frame region outside the pixel formation portions 30. The gate driver 21 outputs control signals that control timing at which the switching elements 31 are turned on/off, to gate wiring lines GL. The source driver 22 outputs video signals allowing the pixel formation portions 30 to display video and control signals that control timing at which the video signals are outputted, to source wiring lines SL.

By activating the gate wiring lines GL in turn to place those switching elements 31 connected to the activated gate wiring line GL in an on state, video signals provided to the source wiring lines SL are provided to corresponding pixel electrodes 32 through the switching elements 31. The pixel electrodes 32 form pixel capacitances with a common electrode (not shown) formed on the CF substrate, and hold the provided video signals. As a result, backlight light according to the video signals is transmitted through corresponding pixel formation portions 30, thereby displaying video on the liquid crystal panel 10.

By forming the switching elements 31 of the pixel formation portions 30 of a liquid crystal display device using TFTs 100 to 300 described in the above-described embodiments, since the contact resistance of the TFTs 100 to 300 is low, the current flowing through the switching elements 31 can be increased. By this, the switching elements 31 can charge video signals provided from the source wiring lines SL in their pixel capacitances in a short time, enabling to achieve high definition of the liquid crystal panel 10 by increasing the number of pixel formation portions 30.

In addition, in the case of forming the gate driver 21 and the source driver 22 on the TFT substrate 20 using continuous grain silicon, by forming the gate driver 21 and the source driver 22 using TFTs 100 to 300, the operating speed of the gate driver 21 and the source driver 22 can be increased. As a result, the circuit size of the gate driver 21 and the source driver 22 decreases, enabling to reduce the size of the picture-frame of the liquid crystal panel 10 and achieve low power consumption of the liquid crystal display device.

### 5. Others

The present invention can also be favorably used for inverted coplanar type and coplanar type TFTs, in addition to inverted staggered type or staggered type TFTs such as those described above. Effects brought about in the case of application to inverted coplanar type and coplanar type TFTs are the same as those in the case of application to inverted staggered type or staggered type TFTs and thus description thereof is omitted.

It is described that a semiconductor material that forms contact layers 150a to 350a and 150b to 350b composing TFTs 100 to 300 according to the above-described embodiments is silicon. However, the contact layers 150a to 350a and 150b to 350b may be formed of a semiconductor material such as silicon-germanium.

Although it is described that the TFTs 100 to 300 according to the embodiments are of an n-channel type, they may be of a p-channel type. In this case, p-type impurities such as boron (B) need to be doped in stacked silicon layers serving as the contact layers 150a to 350a and 150b to 350b. A stacked silicon layer having p-type impurities doped therein is deposited by supplying, for example, diborane (B₂H₆) gas instead of phosphine gas into a chamber.

Deposition of stacked silicon layers serving as the contact layers 150a to 350a and 150b to 350b of the TFTs 100 to 300 according to the embodiments uses monosilane gas, but may use dichlorosilane (SiH₂Cl₂) gas or disilane (Si₂H₆) gas.

The TFTs 100 to 300 according to the embodiments are also used in display devices such as organic EL (Electroluminescence) display devices and plasma display devices, in addition to liquid crystal display devices.

### INDUSTRIAL APPLICABILITY

The present invention is suitable for display devices such as active matrix-type liquid crystal display devices, and is particularly suitable for switching elements formed in pixel formation portions of the display devices, or transistors composing a drive circuit that drives the pixel formation portions.

### DESCRIPTION OF REFERENCE CHARACTERS

10: LIQUID CRYSTAL PANEL
20: TFT SUBSTRATE
21: GATE DRIVER
22: SOURCE DRIVER
30: PIXEL FORMATION PORTION
31: SWITCHING ELEMENT
100, 200, and 300: THIN FILM TRANSISTOR (TFT)
115: GLASS SUBSTRATE
120 and 320: GATE ELECTRODE
130 and 330: GATE INSULATING FILM
140 and 340: CHANNEL LAYER
150a, 250a, 350a, 150b, 250b, and 350b: CONTACT LAYER
151a, 151b, 351a, and 351b: n⁺ AMORPHOUS SILICON LAYER
152a, 252a, 352a, 152b, 252b, and 352b: n⁺ MICROCRYSTALLINE SILICON LAYER
153a, 253a, 353a, 153b, 253b, and 353b: n⁺ MICROCRYSTALLINE SILICON LAYER
160a and 360a: SOURCE ELECTRODE
160b and 360b: DRAIN ELECTRODE

1: A semiconductor device comprising a gate electrode, a gate insulating film, a channel layer, and source and drain electrodes stacked on top of one another on an insulating substrate in this order or in reverse order thereto, wherein
the semiconductor device further comprises two contact layers formed between the channel layer and the source electrode and between the channel layer and the drain electrode so as to be separated from each other, and
each of the contact layers has a first microcrystalline semiconductor layer and a second microcrystalline semiconductor layer stacked on top of each other in order of the first microcrystalline semiconductor layer and the second microcrystalline semiconductor layer from a side of the channel layer, the first microcrystalline semiconductor layer containing a conductive impurity, and the second microcrystalline semiconductor layer containing a conductive impurity of a same type as that of the first microcrystalline semiconductor layer and having a higher crystallization rate than the first microcrystalline semiconductor layer.

2: The semiconductor device according to claim 1, wherein
the gate electrode is formed on the insulating substrate,
the gate insulating film is formed so as to cover the gate electrode,
the channel layer is formed on a portion of a surface of the gate insulating film corresponding to the gate electrode,
each of the contact layers is formed such that a stacked film is formed on a surface of the channel layer, the stacked film having the second microcrystalline semiconductor layer stacked on a surface of the first microcrystalline semiconductor layer, and
the source and drain electrodes are respectively formed on surfaces of the second microcrystalline semiconductor layers.

3: The semiconductor device according to claim 1, wherein
the source and drain electrodes are formed on the insulating substrate,
the contact layers are formed such that stacked films are formed on surfaces of the source and drain electrodes, respectively, so as to be spaced from each other by a predetermined distance, the stacked films each having the first microcrystalline semiconductor layer stacked on a surface of the second microcrystalline semiconductor layer,
the channel layer is formed so as to cover a portion of the insulating substrate sandwiched between the contact layers, and surfaces of the first microcrystalline semiconductor layers of the contact layers,
the gate insulating film is formed so as to cover the channel layer, and
the gate electrode is formed on a portion of a surface of the gate insulating film corresponding to the portion of the insulating substrate sandwiched between the contact layers.

4: The semiconductor device according to claim 2, wherein each of the contact layers further includes an amorphous semiconductor layer between the first microcrystalline semiconductor layer and the channel layer, the amorphous semiconductor layer containing a conductive impurity of a same type as that of the first microcrystalline semiconductor layer.

5: The semiconductor device according to claim 4, wherein
each of the first microcrystalline semiconductor layers includes a plurality of microcrystalline semiconductor layers having different crystallization rates, and
the plurality of microcrystalline semiconductor layers include microcrystalline semiconductor layers formed such that crystallization rates thereof increase in turn from the side of the channel layer toward the second microcrystalline semiconductor layer.

6: The semiconductor device according to claim 4, wherein the crystallization rate of the first microcrystalline semiconductor layers is between 1, inclusive.

7: A method for manufacturing a semiconductor device having a gate electrode, a gate insulating film, a channel layer, contact layers, and source and drain electrodes stacked on top of one another in this order on an insulating substrate, wherein
each of the contact layers includes a first microcrystalline semiconductor layer containing a conductive impurity; and a second microcrystalline semiconductor layer containing an conductive impurity of a same type as that of the first microcrystalline semiconductor layer, and
a step of forming each of the contact layers includes:
a step of forming the first microcrystalline semiconductor layer on a surface of the channel layer; and
a step of forming the second microcrystalline semiconductor layer on a surface of the first microcrystalline semiconductor layer at a higher flow ratio of hydrogen gas to raw material gas than that for the step of forming the first microcrystalline semiconductor layer.

8: The method for manufacturing a semiconductor device according to claim 7, wherein the step of forming each of the contact layers further includes:
a step of forming an amorphous semiconductor layer on the surface of the channel layer prior to the step of forming the first microcrystalline semiconductor layer.

9: The method for manufacturing a semiconductor device according to claim 8, wherein
each of the first microcrystalline semiconductor layers includes a plurality of microcrystalline semiconductor layers having different crystallization rates, and
in the step of forming the first microcrystalline semiconductor layer, a flow ratio of hydrogen gas to raw material gas increases in turn for every formation of a microcrystalline semiconductor layer included in the plurality of microcrystalline semiconductor layers.

10: The method for manufacturing a semiconductor device according to claim 8, wherein in the step of forming the first microcrystalline semiconductor layer, the flow ratio of hydrogen gas to raw material gas is 1:25 to 1:75.

11: A display device comprising a semiconductor device according to claim 1 formed on an insulating substrate.
